(19) United States
(12) Patent Application Publication
(10) Pub. No.: US 2014/0264261 A1
(43) Pub. Date: Sep. 18, 2014

(54) LIGHT EMITTING DEVICE ON METAL FOAM SUBSTRATE

(71) Applicants: Michael A. Mastro, Fairfax, VA (US); Francis J. Kub, Arnold, MD (US)

(72) Inventors: Michael A. Mastro, Fairfax, VA (US); Francis J. Kub, Arnold, MD (US)

(21) Appl. No.: 14/200,475

(22) Filed: Mar. 7, 2014

Related U.S. Application Data
(60) Provisional application No. 61/781,652, filed on Mar. 14, 2013.

(51) Int. Cl. H01L 33/06

(52) U.S. Cl. CPC H01L 33/06
USPC 257/13; 438/47

(57) ABSTRACT

A light emitting device having an electrically conductive metal foam or porous metal substrate, one or more light emitting nanowires in contact with the substrate, and a metal or conductive oxide contact layer in contact with each nanowire junction opposite of the substrate. More specifically, a light emitting device having an electrically conductive metal foam substrate, one or more light emitting nanowires in contact with the substrate, a quantum well on the nanowire(s), a p-type shell on the quantum well, a metal or conductive oxide contact layer in contact with the shell, and an energy down-converting material. Also disclosed is the related method of making a light emitting device.

### PRIORITY CLAIM

The present application is a non-provisional application claiming the benefit of U.S. Provisional Application No. 61/781,652, filed on Mar. 14, 2013 by Michael A. Mastro et al., entitled “Light Emitting Device on Metal Foam Substrate,” the entire contents of which is incorporated herein by reference.

### BACKGROUND OF THE INVENTION

1. Field of the Invention

The present invention relates generally to light emitting diodes and, more specifically, to light emitting devices on a metal foam substrate.

2. Description of the Prior Art

The GaN-based light emitting diode (LED) market has grown into a multi-billion dollar market in just two decades. Despite this rapid progress, certain restrictions are inherent to the thin-film on a planar substrate design. These constraints can be generalized into light extraction, defectivity, substrate cost, and processing cost limitations, as well as a lack of mechanical flexibility.

Sapphire is the predominant substrate for epitaxy of III-nitride light emitting diode thin films. Sapphire is non-conductive, limited in size, and presents a large lattice mismatch with the III-nitride material system. Silicon carbide has a closer lattice mismatch to GaN and can be supplied in a conductive state. On the other hand, the silicon carbide substrates are expensive, defective, and limited to four-inches in diameter. Silicon is available in larger diameters but GaN epitaxy on silicon suffers from thermal stress constraints. The cost of the wafer is significant but often overstated when compared to the processing and balance of system costs. A move to larger wafers allows a significant increase in back-end processing throughput and commensurate decrease in the cost per die.

An ongoing idea is to produce III-nitride LEDs on low-cost, large-area substrates such as glass akin to the thin film photovoltaic technologies. Despite some progress for producing III-nitride LEDs on glass, a poly-crystal type growth is inherently produced when the underlying substrate, such as glass, does not present crystalline order to align the reactant atoms of the thin film. Poly-crystal or fine-grain III-nitride material presents an exceedingly large number of dislocations and other defects that effectively destroy operation of the pn junction.

Even for high-quality thin film growth on sapphire, lattice mismatch leads to the formation of dislocations with densities greater than 10⁸ cm⁻², which limit the internal quantum efficiency. Furthermore, green LEDs require high indium content in the InₓGa₁₋ₓN quantum wells that under planar lattice stress can encourage the formation of V-pits. Moreover, InₓGa₁₋ₓN stability is reduced at the elevated growth temperature needed for thin film metal organic chemical vapor deposition (MOCVD).

Another intrinsic issue with a standard LED structure is the low external extraction efficiency of light owing to the index of contrast difference with air. A majority of the light generated in a semiconductor thin film on a planar substrate suffers from total internal refraction. Complex procedures such as die shaping, photonic crystals, micro-cavities, and surface roughening are used to extract light that would normally be trapped in the semiconductor and substrate slab.

Nanowire III-nitride light emitters have been suggested and demonstrated to avoid many of the deleterious issues associated with thin film structures. The dimensions of the nanowire are on the order of the optical wavelength; therefore, light is easily scattered out of the semiconductor into the surrounding air. The growth of nanowires via vapor-liquid-solid mechanism proceeds at a temperature lower than that used for thin-film MOCVD, easing the incorporation of indium into the active region. The removal of the in-plane lattice constraint allows nanowires to grow with a greatly reduced defect level relative to its thin-film equivalent. The vapor-liquid-solid growth of GaN nanowires is known to have a lesser dependence on the underlying substrate.

Recently, a two-step reactive vapor/MOCVD approach was used to grow GaN nanowires with an InGaN shell on a stainless steel substrate. (Pendyala et al., “Nanowires as semi-rigid substrates for growth of thick, InₓGa₁₋ₓN (x>0.4) epilayers without phase segregation for photoelectrochemical water splitting,” Nanoscale, 4, 6269 (2012)). In general, a metal substrate can be scaled to any reasonable process tool size or shape.

### BRIEF SUMMARY OF THE INVENTION

The aforementioned problems are overcome in the present invention which provides a light emitting device having an electrically conductive metal foam or porous metal substrate, one or more light emitting nanowires in contact with the substrate, and a metal or conductive oxide contact layer in contact with each nanowire junction opposite of the substrate. More specifically, a light emitting device having an electrically conductive metal foam substrate, one or more light emitting nanowires in contact with the substrate, a quantum well on the nanowire(s), a p-type shell on the quantum well, a metal or conductive oxide contact layer in contact with the shell, and an energy down-converting material. Also disclosed is the related method of making a light emitting device.

The objective of the present invention is to create a light emitting assembly comprising a III-nitride diode that emits light in the ultraviolet, blue, or green, on a conductive metal foam substrate. The present invention provides a nanowire LED design based on a metal foam substrate. In contrast to a solid metal substrate, the foam form further lowers the amount and cost of material used for a given surface area. Furthermore, the suppleness of the foam substrate extends the application space to other areas including coiled piezoelectric energy harvesting devices and flexible displays. It is expected from simple ray tracing that the vast majority of light generated from the nanowires will not be reabsorbed somewhere else in the architecture. This includes light generated deep in the structure that can be expected to directly escape through the micron-scale pores of the foam substrate.

One embodiment of the present invention provides an electrically conductive metal foam or porous metal substrate and one or more nanowire devices emitting light from a pn junction including junction with a single or multi-quantum well. In another embodiment, the light emitting device comprises a wide-bandgap semiconductor comprising GaN, AlGaN, InGaN, InAlGaN, ZnO, MgZnO, ZnSe, ZnMgSe, CdTe, CdMnTe, and similar alloys. Yet another embodiment provides a light emitting device comprises a narrow- or medium-bandgap semiconductor comprising GaAs, AlGaAs, InGaAs, InP, GaP, CuO₂, CuO, CuS, CuInGaSe₂, CuZnSnS₂, and similar alloys. One more embodiment provides a plurality of light emitting nanowires on a metal foam substrate adjacent to or covered with a luminophoric medium such as a phosphorescent material, a fluorescent material, or a single or a mixture of semiconductor quantum dots. Another embodiment provides a module for UV, blue, or green light illumination. An additional embodiment provides a module for white light illumination.

The subject of this invention allows the design of a light emitting device on a metal foam substrate that is inexpensive, conductive, and can be formed into any reasonable size or shape. The subject can represent a single component in a multiple-component module

These and other features and advantages of the invention, as well as the invention itself, will become better understood by reference to the following detailed description, appended claims, and accompanying drawings.

### BRIEF DESCRIPTION OF THE DRAWINGS

FIG. 1 shows a metal foam substrate with tapered nanowires so that the bases of adjacent nanowires touch.

FIG. 2 is a simplified schematic of a single heterostructure nanowire on a metal foam substrate with an initial thin conformal GaN seed layer formed on the metal substrate.

FIG. 3 is a simplified schematic of a package with multiple nanowire light emitting sources optionally coupled to an energy-down conversion material.

FIG. 4 is an electron micrograph of GaN nanowires on a nickel foam substrate at varying levels of magnification: (a) 100 μm, (b) 50 μm, (c) 5 μm, and (d) 500 nm.

FIG. 5 is an x-ray diffraction pattern of GaN nanowires on a nickel foam substrate.

FIG. 6 shows the photoluminescence intensity of GaN nanowires on a nickel foam substrate.

FIG. 7 shows the photoluminescence spectrum of GaN:Mg/InGaN well/GaN:Si nanowires on a nickel foam substrate.

### DETAILED DESCRIPTION OF THE INVENTION

The present invention provides light emitting nanowire diodes on a metal foam substrate for illumination. The design includes: an electrically conductive metal foam or porous metal substrate; one or more multi-layer semiconductor nanowire light emitting diodes formed in contact with the substrate with a continuous pn junction; a metal coating or conductive oxide layer used to provide an electrical contact to the side of the diode junction opposite the metal substrate; and a package or module to protect and provide electrical or optical stimulation to the device in a continuous or modulated manner. As shown in FIG. 1, the nanowires may have horizontal/vertical growth-regimes that combine to produce a nanowire that is tapered so that the bases of adjacent nanowires touch. As shown, in FIG. 2, there may be an initial thin conformal GaN seed layer formed on the metal substrate by ALE, MOCVD, MBE, PLD or similar technique.

The substrate can be a metal foam, a porous metal, aligned electrospun metal nano-fibers, or a metal nano-fiber mat. The substrate may comprise a single metallic element, an alloy of several metals, or a multi-phase mixture. The metal foam or porous metal substrate may comprise nickel, copper, stainless steel, other conductive metal material, or any combination thereof.

As shown in FIG. 2, the growth via a catalyst seed (e.g. nickel) by a vapor-liquid-solid mechanism creates a pseudo one-dimensional n-type GaN core on the surface of the metal foam substrate. A thin n-type GaN coating will likely deposit on the surface of the metal foam in the remaining area where the nanowires are not formed. Subsequently, a thin InGaN quantum well and thicker GaN:Mg shell will be forced around the GaN:Si core. A sputtered metal, evaporated metal, transferred grapheme, deposited conductive oxide or similar will be used to contact the p-type layer.

Alternatively, an MOCVD growth process can deposit the nanowire light emitting structure, or this structure can be created by molecular beam epitaxy (MBE), hydride vapor phase epitaxy (HVPE), pulsed laser deposition (PLO), atomic layer deposition (ALO), aqueous solution, hydrothermal, solvothermal and variants.

The light emitting device may comprise any wide-bandgap semiconductor including GaN, AlGaN, InGaN, InAlGaN, ZnO, MgZnO, ZnSe, ZnMgSe, CdTc, CdMnTe, ZnS, and similar alloys where a high energy emission is down-convened to produce a white light source.

The light emitting device may comprise any medium-bandgap or narrow-bandgap semiconductor including GaAs, AlGaAs, InGaAs, InP, GaP, CuO₂, CuO, CuS, CuInGaSe₂, CuZnSnS₂, and similar alloys.

The structure may be designed with n- and p-regions to inject electrons and holes, respectively, into a quantum single or multi-quantum well, or pn hetero- or homo-junction. The semiconductor pn junction or the semiconductor/metal junction can be used as a photovoltaic device to convert photons to electrons. The semiconductor pn junction or the semiconductor/metal junction can be used to rectify current. The semiconductor pn junction or the semiconductor/metal junction can be used to convert ambient mechanical energy such as vibrations into an electrical current via piezoelectric effect.

An evaporation, sputtering, or similar technique is used to form a conductive metal layer to provide contact to the diode junction opposite the metal substrate. A conductive oxide or graphene can also provide the contact to the diode junction opposite the metal substrate.

FIG. 3 shows a package or module to protect and provide electrical or optical stimulation to the device. A down-converting luminophoric medium may be arranged in close proximity to the light source. The light emitting device emits a high energy emission that may be down-converted to produce a white light source. The package may serve as a white light source in automobiles, general room or outside lighting, LCD or similar backlight.

FIG. 4 is an electron micrograph of GaN nanowires on a nickel foam substrate at varying levels of magnification: (a) 100 μm, (b) 50 μm, (c) 5 μm, and (d) 500 nm. Images of the GaN nanowires on the nickel foam framework are observable in a series of scanning electron micrographs. The nanowires grow uniformly over the entire foam surface. This particular foam has pores with an average diameter of 200 μm, although a similar uniform coating was achieved for pore diameters down to 5 μm. At smaller pore volumes, it is possible to form a coalesced film. The GaN wire length is proportional to growth time with 1 hour of growth yielding wires of approximately 10 μm in length. The GaN nanowires have an approximate 200 nm diameter over a length of several microns. A slight tapering is evident owing to growth at an elevated nanowire growth temperature, although these conditions are known to produce higher quality GaN nanowires.

FIG. 5 is an x-ray diffraction pattern of GaN nanowires on a nickel foam substrate. While the nanowires grow along the a-plane direction, the curvature of the underlying foam presents a range of diffracting planes at the nominal surface. A 2Θ-Θ x-ray diffraction pattern presents sharp diffraction from the (10-10), (0002), and (10-10) planes as well as weaker diffraction from higher index planes.

FIG. 6 shows the photoluminescence intensity of GaN nanowires on a nickel foam substrate. The room temperature PL of the GaN nanowires displays two major bands in the spectrum corresponding to the band-edge and the donor-acceptor luminescence transitions. The dominant band at 3.4 eV is associated with recombination processes involving the annihilation of free-excitons and band-to-band transition. The enhancement of the higher energy side the band-edge PL emission is typically attributed to the high-excess of free electron carriers in high-quality GaN.

FIG. 7 shows the photoluminescence spectrum of GaN:Mg/InGaN well/GaN:Si nanowires on a nickel foam substrate. Samples were fabricated with a GaN:Si core followed by the formation of an InGaN-well/GaN:Mg shell around the core. The thickness of the InGaN shell layer is approximately 5 nm and, the outer thickness of the GaN:Mg layer is 200 nm after 5 min of growth. The thickness of the InGaN/GaN:Mg sheath was directly proportional to growth time. The structure of the nano-wires was designed to create a thin InGaN well for quantum confinement of the injected carriers, and a thicker GaN:Si core and GaN:Mg sheath for optical confinement of the optical mode. The PL spectrum from GaN:Mg/InGaN well (sheath)/GaN:Si (core) nano-wires displays the expected GaN band-edge (near 3.4 eV) and near band-edge dopant-based transitions as well as the 542 nm InGaN luminescence from the quantum well.

The light emitter may be used to send a modulated signal between various objects such as two cars for communication. The modulation rate can be set at a level that cannot be distinguished by the human eye. The light emitting layer can be shaped as one or more dots, or one or more wires.

The semiconductor/metal structure can used to obscure or interface with electromagnetic energy over a broad range or a multitude of ranges. The semiconductor/metal structure can be annealed or pressed to form a denser packing, connect the nanofibers, or improve the properties of the structure.

The above descriptions are those of the preferred embodiments of the invention. Various modifications and variations are possible in light of the above teachings without departing from the spirit and broader aspects of the invention. It is therefore to be understood that the claimed invention may be practiced otherwise than as specifically described. Any references to claim elements in the singular, for example, using the articles “a,” “an,” “the,” or “said,” is not to be construed as limiting the element to the singular.

What is claimed as new and desired to be protected by Letters Patent of the United States is:

1. A light emitting device, comprising:
an electrically conductive metal foam or porous metal substrate;
one or more light emitting nanowires in contact with the substrate; and
a metal or conductive oxide contact layer in contact with each nanowire junction opposite of the substrate.

2. The light emitting device of claim 1, wherein the substrate comprises nickel, copper, stainless steel, or any combination thereof.

3. The light emitting device of claim 1, wherein the one or more nanowire comprise III-nitride.

4. The light emitting device of claim 1, wherein the one or more nanowires are formed using a vapor-liquid-solid mechanism.

5. The light emitting device of claim 1, additionally comprising a GaN seed layer on the metal substrate.

6. The light emitting device of claim 1, additionally comprising an energy down-converting material.

7. The light emitting device of claim 1, wherein the light emitting device comprises a wide-bandgap semiconductor comprising GaN, AlGaN, InGaN, InAlGaN, ZnO, MgZnO, ZnSe, ZnMgSe, CdTc, CdMnTe, ZnS, or any combination thereof; or wherein the light emitting device comprises a narrow- or medium-bandgap semiconductor comprising GaAs, AlGaAs, InGaAs, InP, GaP, CuO₂, CuO, CuS, CuInGaSe₂, CuZnSnS₂, or any combination thereof.

8. The light emitting device of claim 1, wherein a quantum well is formed on the one or more nanowires.

9. The light emitting device of claim 8, wherein a p-type shell is formed on the quantum well.

10. The light emitting device of claim 1, wherein the nanowires form a continuous pn junction.

11. A light emitting device, comprising:
an electrically conductive metal foam substrate;
one or more light emitting nanowires in contact with the substrate;
a quantum well on each nanowire;
a p-type shell on the quantum well;
a metal or conductive oxide contact layer in contact with the shell; and
an energy down-converting material.

12. The light emitting device of claim 11, wherein the one or more nanowires comprise GaN, the quantum well comprises InGaN, and the shell comprises GaN.

13. A method of making a light emitting device, comprising:
contacting one or more light emitting nanowires with an electrically conductive metal foam or porous metal substrate; and
contacting a metal or conductive oxide contact layer with each nanowire junction opposite of the substrate.

14. The method of claim 13, wherein the substrate comprises nickel, copper, stainless steel, or any combination thereof.

15. The method of claim 13, wherein the one or more nanowire comprise III-nitride.

16. The method of claim 13, wherein the one or more nanowires are formed using a vapor-liquid-solid mechanism.

17. The method of claim 13, additionally comprising an energy down-converting material.

18. The method of claim 13, wherein the light emitting device comprises a wide-bandgap semiconductor comprising GaN, AlGaN, InGaN, InAlGaN, ZnO, MgZnO, ZnSe, ZnMgSe, CdTc, CdMnTe, ZnS, or any combination thereof; or wherein the light emitting device comprises a narrow- or medium-bandgap semiconductor comprising GaAs, AlGaAs, InGaAs, InP, GaP, CuO₂, CuO, CuS, CuInGaSe₂, CuZnSnS₂, or any combination thereof.

19. The method of claim 13, additionally comprising forming a quantum well on the one or more nanowires.

20. The method of claim 19, additionally comprising forming a p-type shell on the quantum well.

21. The method of claim 13, wherein the nanowires form a continuous pn junction.
